(19) United States
(12) Patent Application Publication
(10) Pub. No.: US 2019/0195448 A1
(43) Pub. Date: Jun. 27, 2019

(54) Motor-Vehicle Headlamp Having an SMD LED Attached by Soldering

(71) Applicant: ZKW GROUP GMBH, Wieselburg (AT)

(72) Inventor: Daniel PETSCH, Gaming (AT)

(21) Appl. No.: 16/331,678

(22) PCT Filed: Aug. 22, 2017
(86) PCT No.: PCT/AT2017/060207

§ 371 Date: Mar. 8, 2019

(30) Foreign Application Priority Data
Sep. 21, 2016 (AT) A 50846/2016

(51) Int. Cl. F21S 41/147; F21S 41/19; H05K 3/34; F21S 41/25; F21S 41/32; H01L 33/62

(52) U.S. Cl. CPC F21S 41/147; F21S 41/19; H05K 3/3436; F21Y 2107/50; F21S 41/25; F21S 41/321; H01L 33/62; H05K 3/3478

(57) ABSTRACT

The invention relates to a motor-vehicle headlamp (1), comprising at least one LED (4; 4a, 4d), which is attached by soldering, as an SMD, to metal surfaces (3-1, 3-2) of a printed circuit board (3) at connection points of said LED, and comprising an optical unit (2; 8), which emits the light emitted by the at least one LED into the traffic space, wherein, in order to set the emission direction of the at least one LED in a specific manner, said LED is attached by soldering with different solder thicknesses (d1, d2) between the connection points (4-1, 4-2) of said LED and the metal surfaces of the printed circuit board.

The invention relates to a motor vehicle headlamp with at least one LED soldered onto metal surfaces of a printed circuit board with its connections as an SMD, as well as with an optical unit that emits light emitted from the at least one LED into the traffic space.

One problem with headlamps of this kind lies in the fact that an LED as such has a very small emission surface area, but in practice requires a printed circuit board, on which it is connected with live conductor paths by soldering. Within the framework of the present invention, the LED's are configured as SMD (surface mounted device) components, which with their electrical connections most often referred to as “pads” are soldered directly onto the printed circuit board, wherein a reflow process is used. First and foremost, however, the printed circuit board is most often required in conjunction with cooling elements arranged thereon for cooling the LED or LED's, because the absence of suitable cooling would result in the destruction of high-performance LED's used in the headlamp area, but in any event lead to an unacceptable reduction in their service life.

However, the printed circuit board in the headlamp poses a problem for its optical unit, since the LED or LED's soldered thereon lie parallel to the printed circuit board plane, and cannot be adjusted in terms of their emission direction without taking special measures. As a result, a portion of the light emitted by the LED or LED's remains unused and/or, when utilizing a reflector in the headlamp, the printed circuit board can shade a portion of the light emitted by the reflector.

Let it further be noted at this juncture that, as opposed to numerous other conventional lamps, LED's only have a limited opening angle, and thus emit at a partial angle relative to a spherical surface, so that optical units suitable for incandescent lamps cannot uncritically be used, and specific problems that reduce the overall efficiency arise, which will be described further below.

Known from publications WO 2011099328 A1, US 2014319200 A1 and CN 201708701 U are SMD-LED's that are no longer arranged parallel to a printed circuit board due to different solder thicknesses. The LED's are rather specifically inclined so as to achieve desired directions of emission. However, the accompanying technical fields involve backlights for LCD's, an image density detector or an LED fluorescent tube, but not the area of motor vehicle headlamp construction, and also comprise no additional optical units downstream from the LED's for emitting the LED light into the traffic space.

An object of the invention is to eliminate the mentioned disadvantages, if at all possible without any additional costs, and thereby increase the overall efficiency of the headlamp.

Proceeding from a headlamp of the kind mentioned at the outset, this object is achieved according to the invention by soldering on the at least one LED with different solder thicknesses between its connections and the metal surfaces of the printed circuit board in order to specifically set the emission direction thereof.

The invention makes it possible to “adjust” the emission direction for one or several LED's, and thus optimally utilize the light emitted by the LED's without de facto incurring additional costs.

An expedient variant of the invention can provide that the optical unit be designed as a lens system having at least one lens, and a printed circuit board with at least two LED's arranged spaced apart from a lens approximately normal to the optical axis, wherein LED's lying outside of the optical axis with different solder thicknesses between their connections and the metal surfaces of the printed circuit board are arranged in such a way that their primary emission direction is directed toward the center of the lens.

In this way, the light from the LED's placed outside of the optical axis, which are now inclined relative to the optical axis, can be better utilized, and the overall efficiency can be increased.

Another expedient variant is characterized in that the optical unit is designed as an optical reflector unit and has a half-shell reflector, wherein the printed circuit board with the at least one LED lies essentially in the section plane that also contains the optical axis, wherein the at least one LED with different solder thicknesses between its connections and the metal surfaces of the printed circuit board is arranged in such a way that its primary emission direction is inclined relative to the reflector.

This configuration also makes it possible to increase the level of efficiency, and the printed circuit board is prevented from shadowing the emitted light.

It is here especially advantageous if the reflector is a paraboloid half-shell reflector.

In some cases, it may make sense to provide that a lens system with at least one lens additionally be allocated to the reflector.

The invention along with additional advantages will be explained below based on exemplary embodiments, which are illustrated in the drawing. Shown therein on:

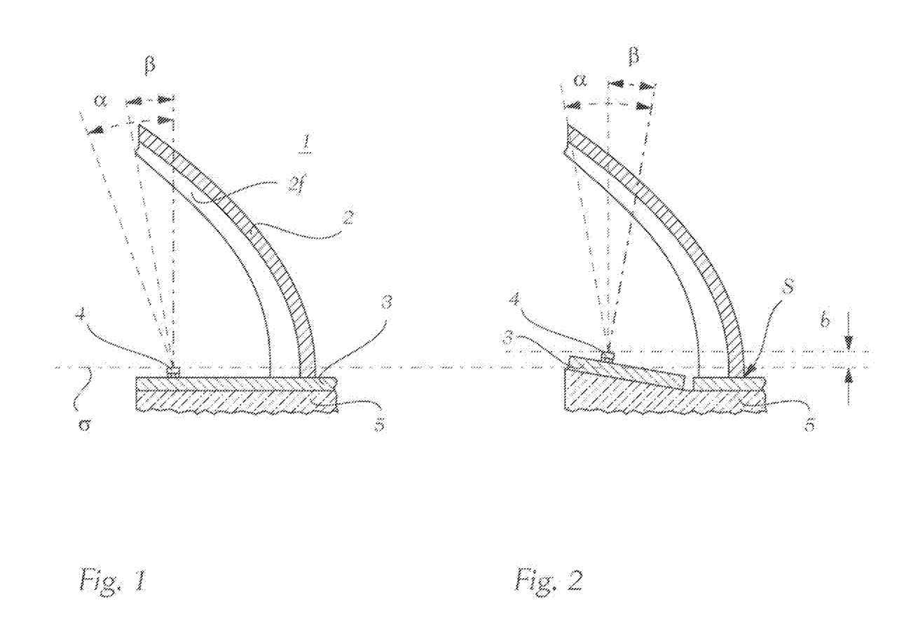

FIG. 1 is a half-shell reflector of a headlamp according to prior art in a schematic section with an LED light source arranged on a printed circuit board,

FIG. 2 is a view as on FIG. 1, but with an inclined printed circuit board, upon which is arranged an LED light source,

FIG. 3 in a view as on FIG. 1 or 2 is the principle solution according to the invention,

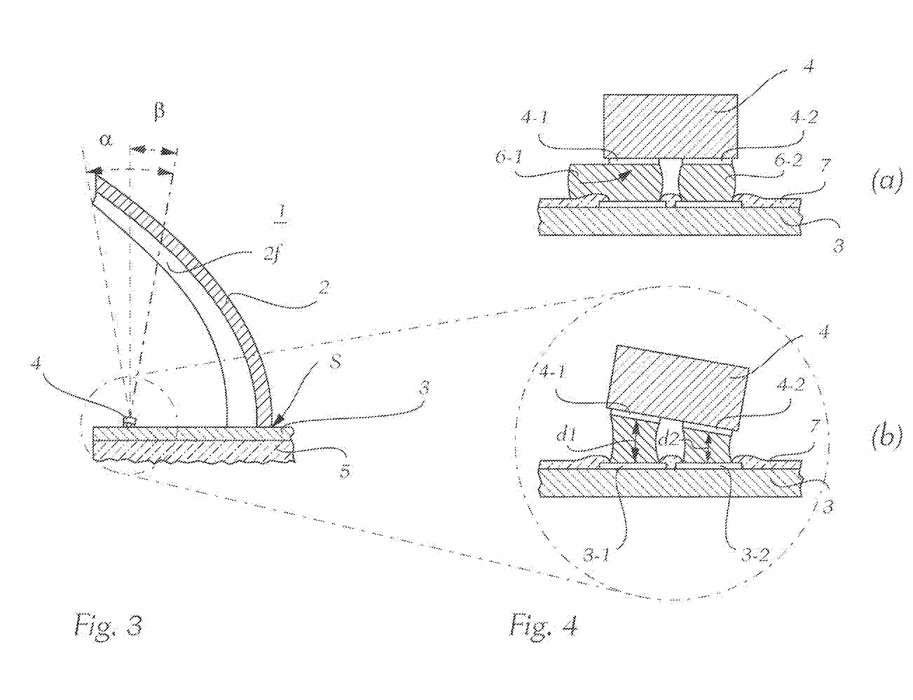

FIG. 4a in a sectional view is the arrangement of an LED configured like an SMD component on a printed circuit board before a reflow soldering process,

FIG. 4b in a view as on FIG. 4a is the final inventive arrangement of the LED on a printed circuit board segment after the reflow soldering process,

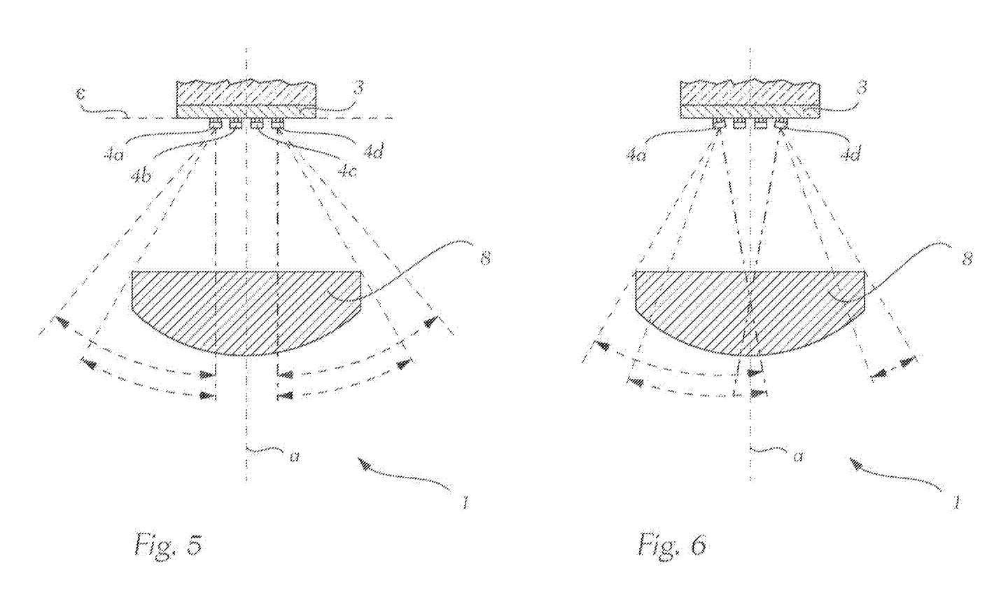

FIG. 5 is a lens of a headlamp according to prior art in a schematic view with four LED light sources arranged on a printed circuit board, and

FIG. 6 is a view as on FIG. 5, but with two LED light sources inclined against the printed circuit board according to the invention.

Visible in reference to FIG. 1 is a headlamp 1 according to prior art with a half-shell reflector 2 as the optical unit, in which an LED light source 4 is arranged on a printed circuit board 3. Reference number 5 denotes a cooling element or a portion of the housing of the headlamp 1. In one embodiment, the half-shell of the reflector 2 is less a paraboloid than a stringing together of facets, but the latter could have been taken from a paraboloid surface. One facet is shown in a sectional view, while an adjacent one provides a shallow-angle view of the interior reflector surface 2f, which here only has a slight enclosure. The printed circuit board 3 with the LED light source 4 lies essentially in a section plane a, which also contains the optical axis of the headlamp 1 (not denoted in any more detail). The reflector opening is located in the area of the focal point or location of the light source 4. In this example, only beams at an angle β of approx. 10° measured from the primary emission direction of the LED strike the interior reflector surface 2f at an overall angle of emission exceeding a from the half-space in the direction in which light exits the reflector.

As shown on FIG. 2, the printed circuit board 3 can now be inclined more toward the interior of the reflector 2 in an attempt to increase the light yield. Depicted is a printed circuit board 3 inclined by approx. 10° toward the parabola apex S, so that beams strike the interior reflector surface 2f at an angle α of up to 20° measured from the primary emission direction of the LED. However, this results in a shadowing of an area of the interior reflector surface 2f near the parabola apex S. On FIG. 2, this is the area b between the recorded dot-dashed lines. Of course, this shadowing again leads to light losses, and is also undesirable from a photometric standpoint.

In conjunction with FIGS. 4a and 4b, FIG. 3 shows how the problem is resolved according to the invention. Only the light source, specifically an SMD-LED 4, is inclined by 10° against the printed circuit board 3, so that beams strike the reflector surface at an angle α of up to 20° measured from the primary emission direction, without shadowing additional parts of the reflector surface.

To achieve the above, the emission direction of the at least one LED 4 is specifically adjusted by soldering it on at different solder thickness between its connections and the metal surfaces of the printed circuit board. This will now be explained in detail based on FIGS. 4a and 4b.

In a highly magnified section in which the cooling element under the printed circuit board 3 has been omitted, FIG. 4b illustrates that the inclination of the SMD-LED 4 is based on different solder thicknesses d1, d2 or soldering gaps of varying thickness between the respective metal surfaces 3-1, 3-2 of the printed circuit board 3 and the SMD-LED 4.

FIG. 4a shows the fitted LED 4 and printed solder 6-1, 6-2 before the reflow process. With respect to the solder joint facing the parabola apex S, the solder 6-2 is only located inside of the area of the metal surface 3-2 of the printed circuit board 3 released by the solder resist 7. The mentioned metal surfaces 3-1, 3-2 are generally lands of conductor paths. At each solder joint that faces the reflector opening, the printed solder 6-1, in addition to the area of the metal surface 3-1 released by the solder resist 7, is also located on the solder resist 7 before the reflow process. The quantity of solder 6-1 in this metal surface 3-1 is measured in such a way that, once the solder has accumulated on the released metal surfaces 3-1, a height for the soldering gap d1 sets in that is larger than for the metal surface 3-2 facing the parabola apex S.

As a result of the different solder thicknesses between the connections 4-1, 4-2 and metal surfaces 3-1, 3-2, the primary emission direction for the LED 4 is inclined relative to the reflector 2, without this producing a shadowing as depicted on FIG. 2. FIGS. 1 to 4 show a motor vehicle headlamp 1 with an optical reflector unit, wherein it must be noted that a lens system containing at least one lens can also be allocated to the reflector in a manner known to the expert.

Based on an example, it will be demonstrated below that the invention can also be applied to a headlamp whose optical unit consists of a lens system. Identical or similar parts are here labeled with the same reference numbers as used above. FIG. 5 shows an optical arrangement for a headlamp 1, which consists of four LED's 4a, 4b, 4c, 4d on a printed circuit board 3 and a lens 8. The LED's 4a, 4b, 4c, 4d lie in a plane ε perpendicular to the optical axis a, and lie at varying distances from the optical axis. In the case of the light-emitting diodes 4a, 4d with the greatest distance to the optical axis, beams which are emitted in an exemplary angular range of up to at most 30° measured from the primary emission direction of the respective LED in the half-plane facing away from the optical axis (center of the lens) strike the light ingress surface of the lens 8. The examined plane encompasses the light sources, more precisely the midpoints of the light emitting surfaces of the LED's, on the one hand, and the optical axis a on the other. As obvious, a portion of the light emitted by the outer LED's 4a, 4d is lost given this arrangement.

FIG. 6 shows a comparable arrangement in which the LED's spaced the farthest apart from the optical axis a are mounted inclined relative to the plane of the printed circuit board 3, so that the primary emission direction of these LED's is inclined toward the center of the lens 8. Beams that are emitted at up to an exemplary angle of 40° as measured from the primary emission direction of the LED in the half-plane facing away from the optical axis strike the light ingress surface of the lens during assembly of the LED's with this orientation of the light emission surfaces of the LED's.

Even if not shown in detail, it should be obvious to the expert that the described inclination of the outer LED's is achieved in the same way as explained in greater detail for the embodiment on FIGS. 4a and b, specifically by soldering the LED's 4a, 4d with different solder thicknesses between their connections and the metal surfaces of the printed circuit board in order to set their emission direction in a targeted manner. As should further be evident, the invention can likewise be applied given other numbers of LED's, for example given three LED's in conjunction with FIG. 6, wherein one LED lies centrally in the optical axis. Concentric LED arrangements are also possible.

Within the framework of the invention, the term “LED” should very generally be understood as a light-emitting SMD element, for example to also include so-called multichip LED's, which have several light-emitting surfaces, blue LED's in conjunction with a fluorescent material that emit a “white” mixed light.

Even though only two connections of an LED were shown above and soldered on with different solder thicknesses, it should be evident that the invention similarly comprises light-emitting SMD elements with three or more connections, as long as corresponding solder thicknesses ensure the desired inclination of the LED's.

Reference List

| | | | |
|---|---|---|---|
| 1 | Headlamp | a | Optical axis |
| 2 | Optical unit, reflector | b | Area |
| 2f | Interior reflector surface | d1 | Solder thickness |
| 3 | Printed circuit board | d2 | Solder thickness |
| 3-1 | Metal surface of 3 | S | Parabola apex |
| 3-2 | Metal surface of 3 | α | Overall emission angle |
| 4 | LED, SMD-LED | β | Angle |
| 4 a-d | LED | ε | Plane |
| 4-1 | Connection of 4 | σ | Section plane |
| 4-2 | Connection of 4 | | |
| 5 | Cooling element | | |
| 6-1 | Solder | | |
| 6-1 | Solder | | |
| 7 | Solder resist | | |
| 8 | Lens | | |

1. A method for specifically setting the emission direction of at least one LED (4) in a motor vehicle headlamp (1), with at least one LED (4) soldered onto metal surfaces (3-1, 3-2) of a printed circuit board (3) with its connections (4-1, 4-2) as an SMD, wherein the metal surfaces are released by a solder resist (7), as well as with an optical unit that emits light emitted from the at least one LED into the traffic space, the method comprising:
soldering the at least one LED (4) with different solder thicknesses (d1, d2) between its connections (4-1, 4-2) and the metal surfaces (3-1, 3-2) of the printed circuit board (3) in order to specifically set the emission direction thereof, wherein a quantity of solder (6-1) also extending onto the solder resist (7) is pressed onto the printed circuit board before the reflow process given a metal surface (3-1) that belongs to a connection (4-1, 4-2) with a larger solder thickness, so that once the solder has accumulated on the released metal surface, a height for the soldering gap (d1) sets in that is larger than for the metal surface (3-2) with a smaller solder thickness.

2. The method according to claim 1, wherein the optical unit is designed as a lens system having at least one lens (8), and a printed circuit board (3) with at least two LED's (4a, 4b, 4c, 4d) is arranged spaced apart from a lens approximately normal to the optical axis (a), wherein LED's (4a, 4d) lying outside of the optical axis with different solder thicknesses between their connections and the metal surfaces of the printed circuit board are arranged in such a way that their primary emission direction is directed to a point on the optical axis of the lens.

3. The method according to claim 1, wherein the optical unit is designed as an optical reflector unit and has a half-shell reflector (2), wherein the printed circuit board (3) with the at least one LED (4) lies essentially in the section plane (σ) that also contains the optical axis, wherein the at least one LED with different solder thicknesses (d1, d2) between its connections (4-1, 4-2) and the metal surfaces (3-1, 3-2) of the printed circuit board is arranged in such a way that its primary emission direction is inclined relative to the reflector (2).

4. The method according to claim 3, wherein the reflector is a paraboloid half-shell reflector (2).

5. The method according to claim 3, wherein a lens system with at least one lens is additionally allocated to the reflector.
